(19) United States
(12) Patent Application Publication
(10) Pub. No.: US 2010/0224977 A1
(43) Pub. Date: Sep. 9, 2010

(54) Semiconductor device and method for fabricating the same

(75) Inventor: Kyung-Man Kim, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/656,294

(22) Filed: Jan. 25, 2010

(30) Foreign Application Priority Data
Mar. 3, 2009 (KR) 10-2009-0018129

(51) Int. Cl. H01L 25/065; H01L 23/538

(52) U.S. Cl. 257/686; 257/774; 257/E23.169; 257/E25.013

(57) ABSTRACT

Provided are a semiconductor device and a method for fabricating the same. The semiconductor device may include a substrate including a cell area and a scribe lane area defining the cell area, at least one pad on the cell area, at least one through electrode penetrating the substrate and electrically connected to the at least one pad, and at least one dummy through electrode penetrating the substrate and spaced apart from the at least one through electrode. The semiconductor device may further include at least one conductive pattern on the substrate electrically connecting the at least one through electrode to the at least one dummy through electrode.

### CROSS-REFERENCE TO RELATED APPLICATIONS

This application claims priority under 35 U.S.C. §119 to Korean Patent Application No. 10-2009-0018129, filed on Mar. 3, 2009, in the Korean Intellectual Property Office (KIPO), the entire contents of which are herein incorporated by reference.

### BACKGROUND

1. Field

The present invention relates to semiconductors and, more specifically, to a semiconductor device including a through electrode and a method for fabricating the same.

2. Description of Related Art

The recent trend of electronic products is toward smaller size, lighter weight, higher speed, and higher capacity. This leads to change of strategies in semiconductor devices such as semiconductor chips or semiconductor packages. In recent years, semiconductor packages have been intensively developed. A semiconductor package allows a plurality of semiconductor chips to be integrated into a single semiconductor device by stacking the semiconductor chips.

Semiconductor packaging technologies allow an area occupied by a semiconductor package to be remarkably reduced and are suitable to achieve high capacity of memory devices. A semiconductor package, such as a system in package (SIP), is suitable to integrate functions of semiconductor packages.

There are several methods for stacking semiconductor chips. One method uses a redistribution process on a semiconductor chip to vary an upper structure of the semiconductor chip, and another method uses a through hole formed at a semiconductor chip. The semiconductor packaging using a through-hole exhibits advantages such as high performance, high density, and low profile of semiconductor products.

### SUMMARY

Example embodiments of the present inventive concepts provide a semiconductor device and a method for fabricating the same.

In accordance with an example embodiment of the inventive concepts, a semiconductor device may include a substrate including a cell area and a scribe lane area defining the cell area, at least one pad on the cell area, at least one through electrode penetrating the substrate and electrically connected to the at least one pad, and at least one dummy through electrode penetrating the substrate and spaced apart from the at least one through electrode. The semiconductor device may further include at least one conductive pattern on the substrate electrically connecting the at least one through electrode to the at least one dummy through electrode.

In accordance with an example embodiment of the inventive concepts, a semiconductor device may include a plurality of stacked semiconductor chips, each of the semiconductor chips of the plurality of stacked semiconductor chips including a substrate where a pad is provided, a through electrode electrically penetrating the substrate and electrically connected to the pad, and a dummy through electrode penetrating the substrate and electrically connected to the through electrode via a conductive pattern. In accordance with this example embodiment each of the through electrodes and each of the dummy through electrodes may vertically contact each other and electrically connect to each other to make a parallel electrical connection.

In accordance with an example embodiment of the inventive concepts, a method for fabricating a semiconductor device may include providing a substrate including a cell area and a pad on the cell area. The substrate may further include a scribe lane area defining the cell area. The method may further include removing a portion of the pad and a portion of the substrate below the pad to form a via hole. The method may also include removing a portion of the substrate where the pad is not provided to form a dummy via hole. The method may also include forming a conductive pattern on the substrate between the via hole and the dummy via hole. The method may further include filling the via hole with a first conductive material to form a through electrode electrically connected to the pad and filling the dummy via hole with a second conductive material to form a dummy through electrode electrically connected to the conductive pattern.

In some example embodiments, the semiconductor device may include a substrate including a cell area where a pad is provided and a scribe lane area defining the cell area, a through electrode electrically connected to the pad through which the through electrode penetrates, a dummy through electrode spaced apart from the through electrode and electrically connected to the through electrode, and a redistribution line electrically connecting the through electrode to the dummy through electrode.

In some example embodiments, the semiconductor device may include a plurality of semiconductor chips each including a substrate where a pad is provided, a through electrode electrically connected to the pad through which the through electrode penetrates, and a dummy through electrode electrically connected to the through electrode via a redistribution line. Each of the through electrodes and each of the dummy through electrodes are disposed to vertically contact each other and electrically connect to each other to make a parallel electrical connection.

In some example embodiments, the method may include providing a substrate including a cell area where a pad is provided and a scribe lane area defining the cell area, removing the pad and the substrate below the pad to form a via hole, removing the substrate where the pad is not provided to form a dummy via hole, forming a conductive pattern between the via hole and the dummy via hole to contact the pad, forming a through electrode to fill the via hole and be electrically connected to the pad, and forming a dummy through electrode to fill the dummy via hole and be electrically connected to the pad through the conductive pattern.

### BRIEF DESCRIPTION OF THE DRAWINGS

FIG. 1 is a cross-sectional view of a semiconductor device according to various example embodiment of the present inventive concepts.

FIGS. 2A to 2D are top plan views of a semiconductor devices according to various example embodiments of the present inventive concepts.

FIG. 3 is a cross-sectional view illustrating an electrical connection made by a through-hole in a semiconductor device according to various example embodiments of the present inventive concepts.

FIGS. 4A to 4C are cross-sectional views of a semiconductor package including stacked semiconductor devices according to various example embodiments of the present inventive concepts.

FIG. 5 is a cross-sectional view of a semiconductor device according to various example embodiments of the present inventive concepts.

FIGS. 6A to 6D are top plan views of a semiconductor device according to various example embodiments of the present inventive concepts.

FIGS. 7A to 7G are cross-sectional views illustrating a method for fabricating the semiconductor device according to an example embodiments of the present inventive concepts.

FIGS. 8A to 8G are cross-sectional views illustrating another method for fabricating the semiconductor device according to another example embodiment of the present inventive concepts.

FIG. 9A is a block diagram of a memory card including a semiconductor device according to an example embodiments of the present inventive concepts.

FIG. 9B is a block diagram of a data processing system including a semiconductor device according to an example embodiments of the present inventive concepts.

### DETAILED DESCRIPTION OF THE EXAMPLE EMBODIMENTS

Example embodiments of the inventive concepts will now be described more fully with reference to the accompanying drawings, in which example embodiments are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments.

Example embodiments of the present invention will now be described more fully hereinafter with reference to the accompanying drawings, in which example embodiments of the invention are shown. This invention, however, may be embodied in many different forms and should not be construed as limited to the example embodiments set forth herein. Rather, these example embodiments are provided so that this disclosure will be thorough and complete, and will fully convey the scope of the invention to those skilled in the art. Like numbers refer to like elements throughout.

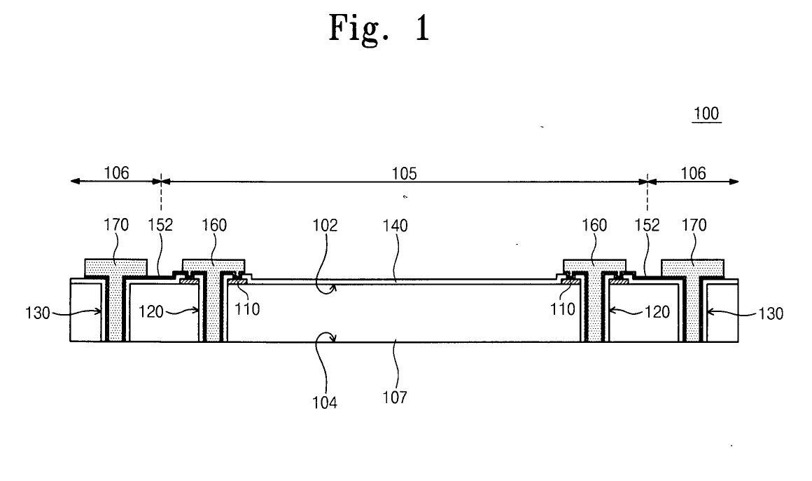

FIG. 1 is a cross-sectional view of a semiconductor device according to some example embodiments of the present inventive concepts. As illustrated, the semiconductor device 100 may be a single-chip semiconductor device, i.e., a semiconductor chip 100 that includes a substrate 107 having a front face (active face) 102 and a back face (inactive face) 104. The substrate 107 may be divided into a cell area 105 where an integrated circuit is formed and an input/output pad 110 electrically connected to the integrated circuit is disposed on the front face 102 and a scribe lane area 106 where a division spot of the substrate 107 is provided to define the cell area 105. The pad 110 may be uniformly distributed at the edge, the center or the front face 102 of the cell area 105. In an example embodiment, a plurality of pads 110 may be disposed at the edge of the cell area 105 to be arranged in a line.

The cell area 105 of the substrate 107 may include a via hole 120 formed to perpendicularly penetrate the substrate 107 and a through electrode 160 disposed to fill the via hole 120 and electrically connect to the pad 110. Similarly, the scribe lane area 106 of the substrate 107 may include a via hole 130 formed to perpendicularly penetrate the substrate 107 and a through electrode 170 disposed to fill the via hole 130 and electrically connect to the pad 110 by a conductive pattern 152. In order to distinguish the via hole 130 and the through electrode 170 formed at the scribe lane area 106 from the via hole 120 and the through electrode 160 formed at the cell area 105, the via hole 130 and the through electrode 170 formed at the scribe lane area 106 will be hereinafter referred to as the dummy via hole 130 and the dummy through electrode 170, respectively.

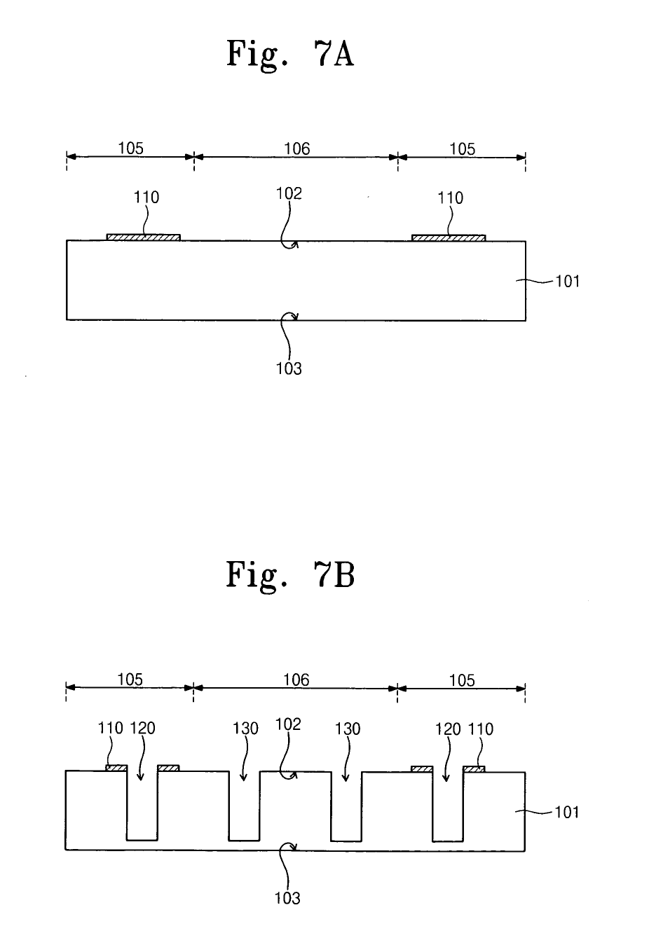

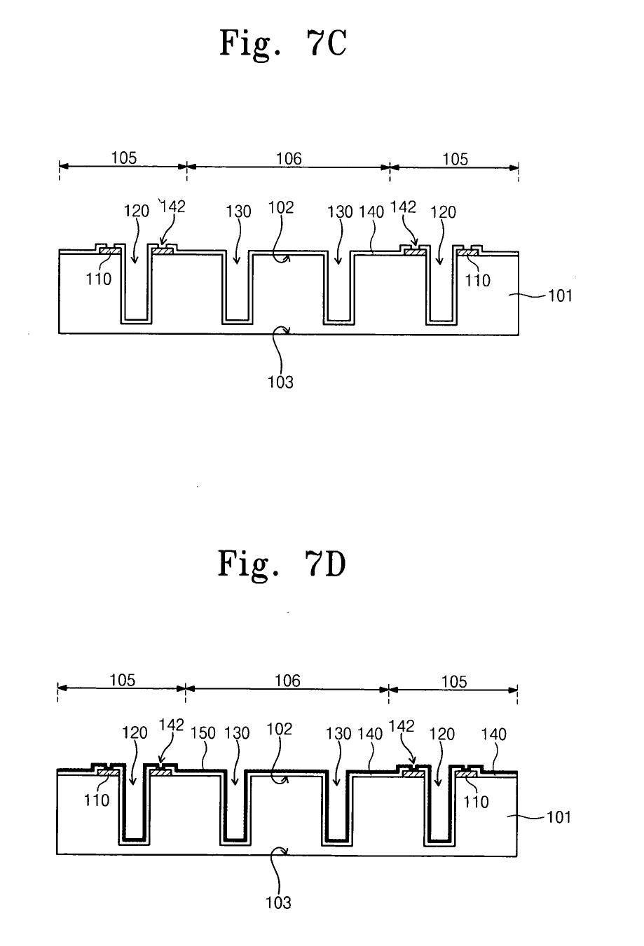

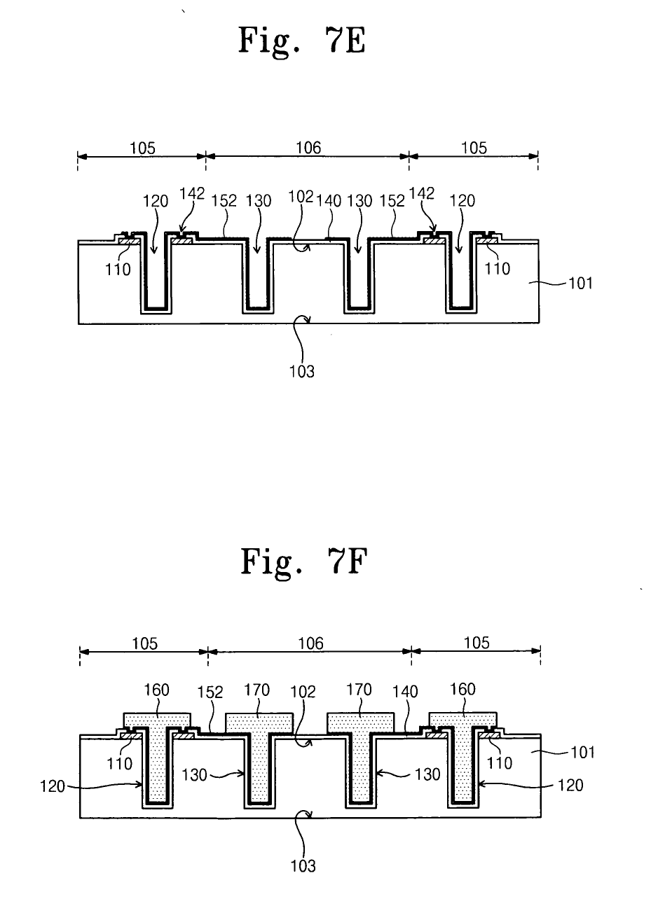

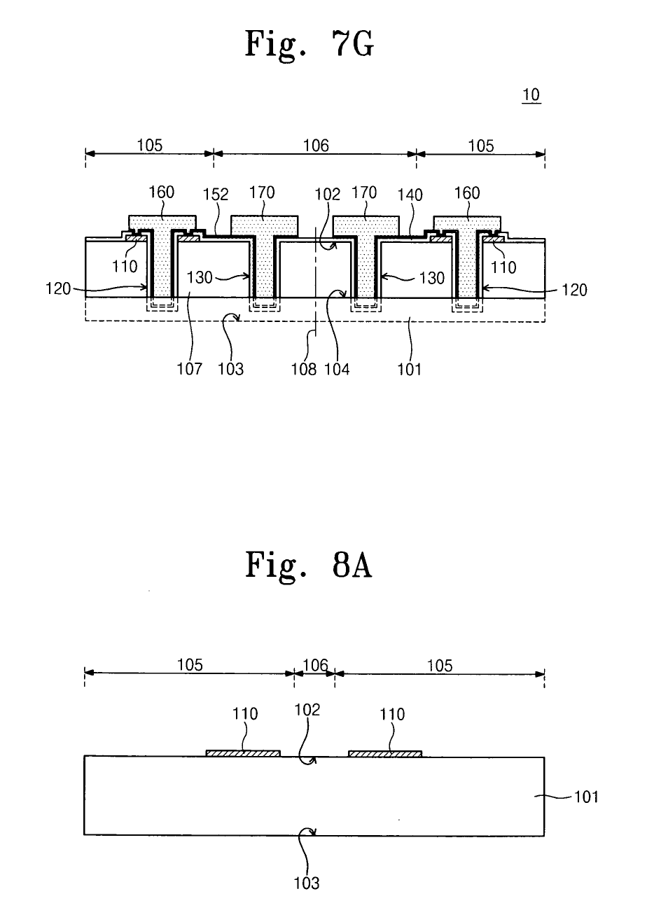

The conductive pattern 152 may be used as a redistribution layer to electrically connect the through electrode 160 and the dummy through electrode 170 with each other. Also the conductive pattern 152 may be used as a seed to form a through electrode 160 and a dummy through electrode 170 by means of an electroplating process, which will be described in detail later with reference to FIG. 7F.

The semiconductor chip 100 may include a passivation layer 140 to protect the front face 102 of the substrate 107. The passivation layer 140 may cover not only the front face 102 but also inner walls of a via hole 120 and a dummy via hole 130. Thus, the passivation layer 140 may be used as not only a protection layer but also an insulating layer to electrically insulate the via hole 120 and the through electrode 160 from each other and electrically insulate the dummy via hole 130 and the dummy through electrode 170 from each other.

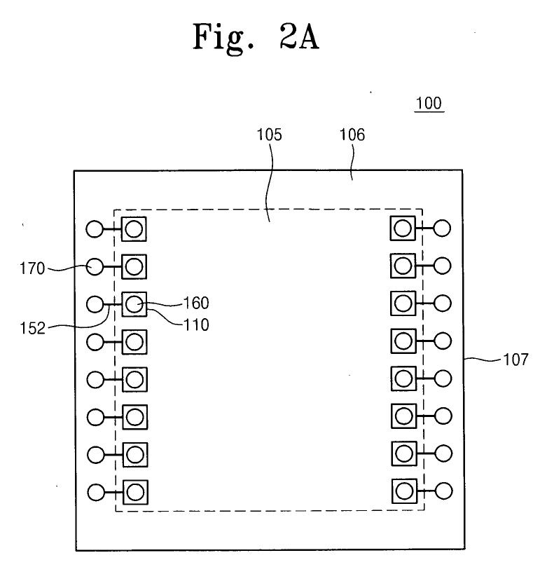

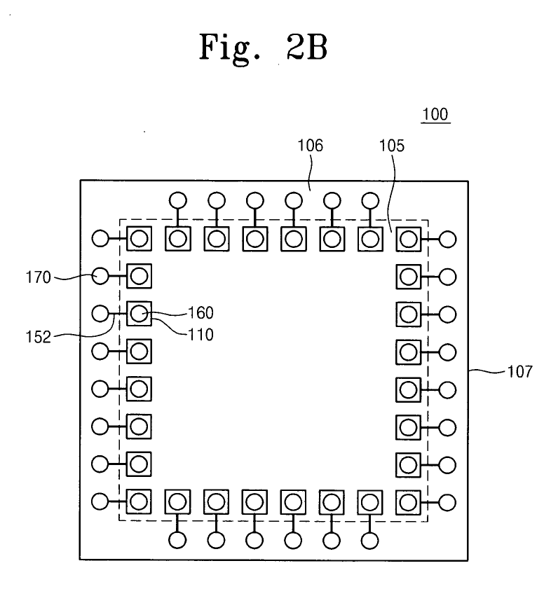

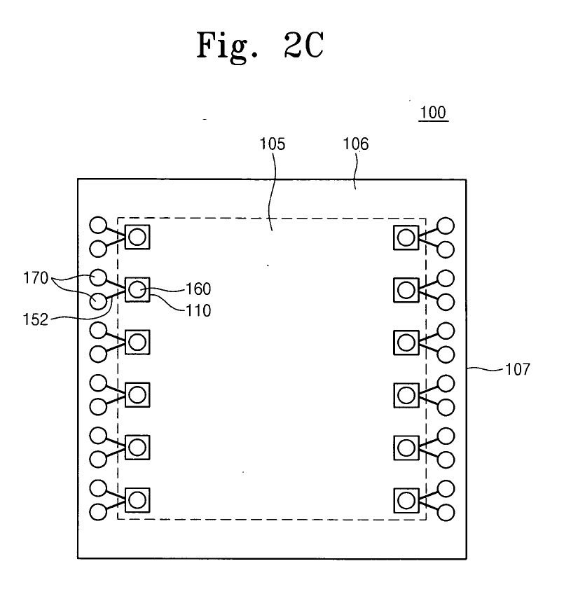

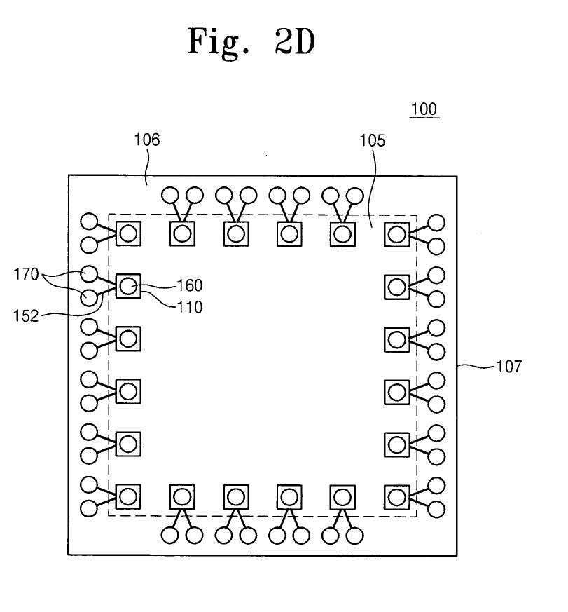

FIGS. 2A to 2D are top plan views of the semiconductor device shown in FIG. 1 according to various example embodiments of the inventive concepts.

FIG. 2A represents a top plan view of the semiconductor device 100 shown in FIG. 1 according to an example embodiment of the inventive concepts. Referring to FIG. 2A, a plurality of pads 110 may be arranged in a line to be adjacent to opposite sides, e.g., both sides (left and right sides) of the cell area 105 in the substrate 107. Also a plurality of through electrodes 160 may be arranged in a line to be adjacent to the left and right sides of the cell area 105. A plurality of dummy through electrodes 170 may be arranged at left and right sides of the scribe lane area 106 in the substrate 107 to establish a one-to-one correspondence to the through electrodes 160 and to be electrically connected to the through electrodes 160 by the medium of the conductive pattern 152.

FIG. 2B represents a top plan view of the semiconductor device 100 shown in FIG. 1 according to another example embodiment of the inventive concepts. Referring to FIG. 2B, a plurality of pads 110 and a plurality of through electrodes 160 may be arranged in a line to be adjacent to four sides (upper, lower, left, and right sides) of the cell area 105 in the substrate 107. Similarly, a plurality of dummy through electrodes 170 electrically connected to the through electrodes 160 by the medium of conductive patterns 152 may be arranged at upper, lower, left, and right sides of the scribe lane area 106 in the substrate 107 to establish a one-to-one correspondence to the through electrodes 160.

FIG. 2C represents a top plan view of the semiconductor device 100 shown in FIG. 1 according to another example embodiment of the inventive concepts. Referring to FIG. 2C, the through electrode 160 and the dummy through electrode 170 may be electrically connected by the medium of the conductive pattern 152 but, unlike the arrangement in FIG. 2A, two dummy through electrodes 170 may correspond to one through electrode 160. At least two dummy through electrodes 170 may be electrically connected to one through electrode 160. That is, one through electrode 160 may be connected to a plurality of dummy through electrodes 170.

FIG. 2D represents a top plan view of the semiconductor device 100 shown in FIG. 1 according to another example embodiment of the inventive concepts. Referring to FIG. 2D, through electrodes 160 and dummy through electrodes arranged the same as shown in FIG. 2B may be electrically connected in the same manner as shown in FIG. 2C. For example, at least two dummy through electrodes 170 may be electrically connected to one through electrode 160.

FIG. 3 is a cross-sectional view illustrating an electrical connection made by a through-hole in a semiconductor device according to some embodiments of the present inventive concepts. For the convenience of explanation, a semiconductor chip is divided into a first semiconductor chip and a second semiconductor chip and each of their components will be divided in the same manner.

Referring to FIG. 3, for example, stacked first and second semiconductor chips 100a and 100b may be electrically connected via first and second through electrodes 160a and 160b which are in vertical contact with each other. In addition, the first and second semiconductor chips 100a and 100b may be electrically connected via first and second dummy through electrodes 170a and 170b which are in vertical contact with each other. A solder 180 may be disposed between the first and second through electrodes 160a and 160b. Similarly, the solder 180 may be disposed between the first and second dummy through electrodes 170a and 170b.

The first through electrode 160a and the first dummy through electrode 170a may be electrically connected by a first conductive pattern 152a, and the second through electrode 160b and the second dummy through electrode 170b may be electrically connected by a second conductive pattern 152b. Accordingly, the through electrodes 160a and 160b and the dummy through electrodes 170a and 170b may be arranged to achieve a parallel electrical connection structure.

Due to the parallel electrical connection, electrical resistance between the first and second semiconductor chip 100a and 100b may be reduced. In the case where an electrical connection between the through electrodes 160a and 160b is poor, a complete electrical connection may be made via the dummy through electrodes 170a and 170b.

For example, in the case where current flow from the first through electrode 160a to the second through electrode 160b is blocked due to a poor contact between the first through electrode 160a and the solder 180 or between the second through electrode 160b and the solder 180, current may flow to the first dummy through electrode 170a from the first through electrode 160a via the medium of the first conductive pattern 152a. The current may flow to the second through electrode 160b and the second dummy through electrode 170b. As a result, an electrical connection between the first and second through electrodes 160a and 160b may be achieved along a bypass.

Besides the electrical characteristics, in terms of mechanical characteristics, a contact with the first and second through electrodes 160a and 160b as well as a contact with first and second dummy through electrodes 170a and 170b is added. Therefore, a strength of adhesion to the first and second semiconductor chips 100a and 100b may be promoted. Moreover, a stress applied to the first and second semiconductor chips 100a and 100b may be distributed via the through electrodes 160a and 160b and the dummy through electrodes 170a and 170b.

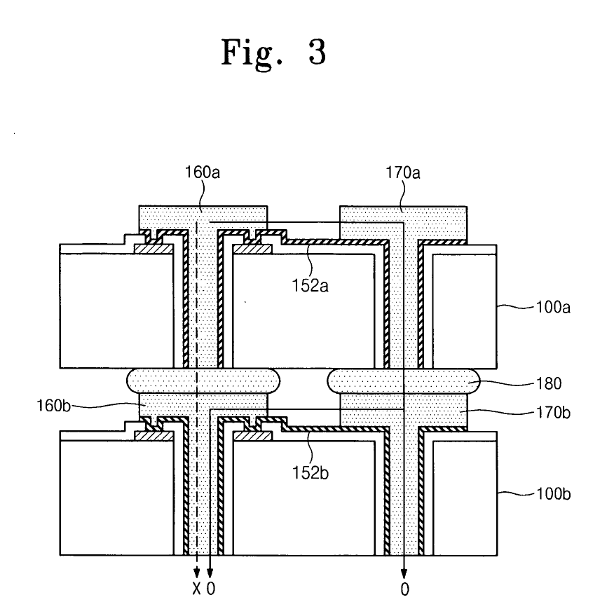

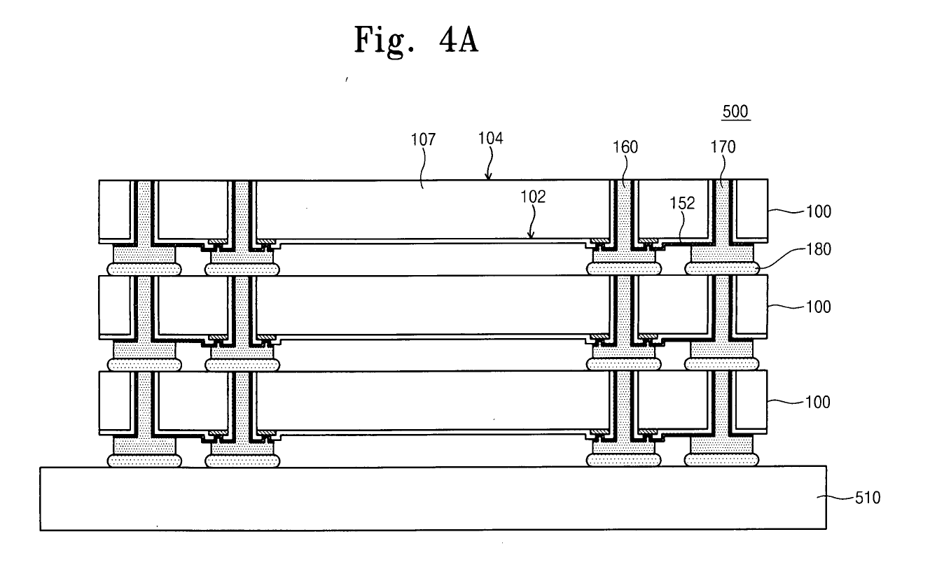

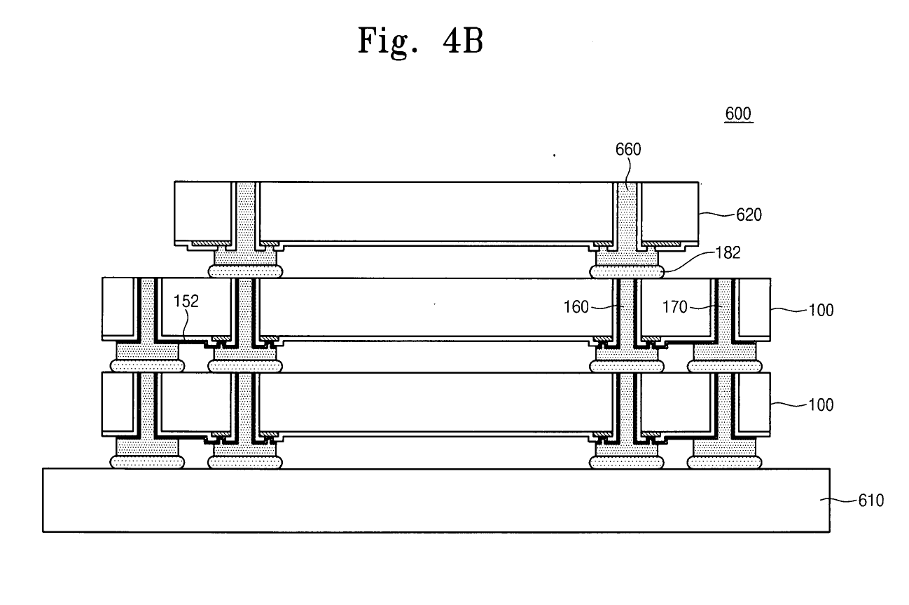

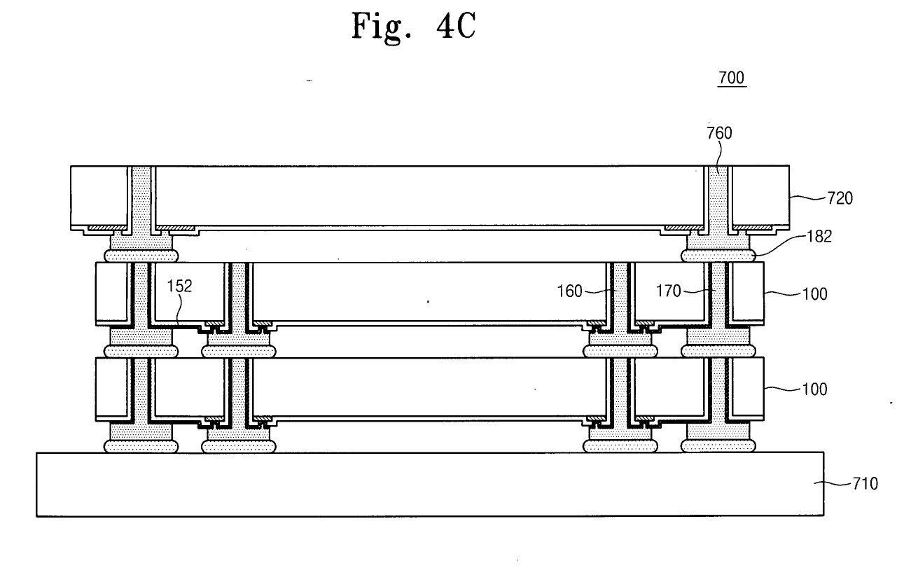

FIGS. 4A to 4C are cross-sectional views of a semiconductor package including stacked semiconductor devices according to various example embodiments of the present inventive concepts. More specifically, FIG. 4A illustrates the same kind of semiconductor chips which are stacked, and FIGS. 4B and 4C illustrate different kinds of semiconductor chips which are stacked.

In this specification, “the same kind of semiconductor chips” may mean semiconductor chips having the same or similar structure and “different kinds of semiconductor chips” may mean semiconductor chips having different structures. For example, “having the same or similar structure” may include “having the same or similar arrangement of through electrodes”. It is regardless of whether a semiconductor chip is a memory chip or a non-memory chip.

Referring to FIG. 4A, a semiconductor package 500 may include a multi-chip package where the semiconductor chips 100 shown in FIG. 1 are vertically stacked. The semiconductor package 500 may further include a printed circuit board (PCB) 510 on which the semiconductor chips 100 are mounted. The semiconductor chips 100 may be stacked on the PCB 510 in a flipped state, i.e., while a front face 102 of a substrate 107 faces an underlying PCB 510 and a back face 104 of the substrate 107 faces up.

Through electrodes 160 may be electrically connected by the medium of a solder 180, and dummy through electrodes 170 may be electrically connected by the medium of a solder 180. The through electrodes 160 and the dummy through electrodes 170 may be electrically connected by a conductive pattern 152. That is, the semiconductor chips 100 may be electrically connected via a parallel electrical connection structure constituted by the through electrode 160 and the dummy through electrode 170. As set forth in FIG. 3, the parallel electrical connection may generate a multi-path of current to reduce resistance and allow current to flow via the dummy through electrode 170 even when current flow via the through electrode 160 is poor.

Since stacking the semiconductor chips 100 may be done by a contact between the through electrodes 160 and a contact between the dummy through electrodes 170, a strength of adhesion between the semiconductor chips 100 may be promoted. Moreover, although a stress may be applied to the semiconductor package 500, it may be distributed via the through electrode 160 and the dummy through electrode 170.

Referring to FIG. 4B, a semiconductor package 600 according to another example embodiment of the inventive concepts may include a printed circuit board (PCB) 610 on which the same kind of semiconductor chips 100 are flipped and stacked, and a different kind of a semiconductor chip 620 may be further stacked on the semiconductor chip 100. The different kind of a semiconductor chip 620 may include a through electrode 660, which may be aligned with a through electrode 160 of the semiconductor chip 100. Accordingly, because the through electrode 660 of the different kind of semiconductor chip 620 is in contact with the through electrode 160 of the semiconductor chip 100 by the medium of a solder 182, the different kind of a semiconductor chip 620 and the semiconductor chip 100 may be electrically connected to each other. Alternatively, the different kind of a semiconductor chip 620 may include a bonding pad instead of the through electrode 660, allowing the bonding pad and the through electrode 160 to be in contact with each other by the medium of a solder ball.

FIG. 4C represents another example of a semiconductor package in accordance with the inventive concepts. Similar to the semiconductor package 600, a semiconductor package 700 shown in FIG. 4C may include a printed circuit board (PCB) 710 on which the same kind of semiconductor chips 100 are flipped and stacked, and a different kind of a semiconductor chip 720 may be further stacked on the semiconductor chip 100. Unlike the semiconductor package 600, the different kind of a semiconductor chip 720 may include a through electrode 760 aligned with a dummy through electrode 170 of the semiconductor chip 100. Accordingly, because the through electrode 760 of the different kind of a semiconductor chip 720 is in contact with the dummy through electrode 170 of the semiconductor chip 100 by the medium of a solder 182, the different kind of a semiconductor chip 170 and the semiconductor chip 100 may be electrically connected to each other.

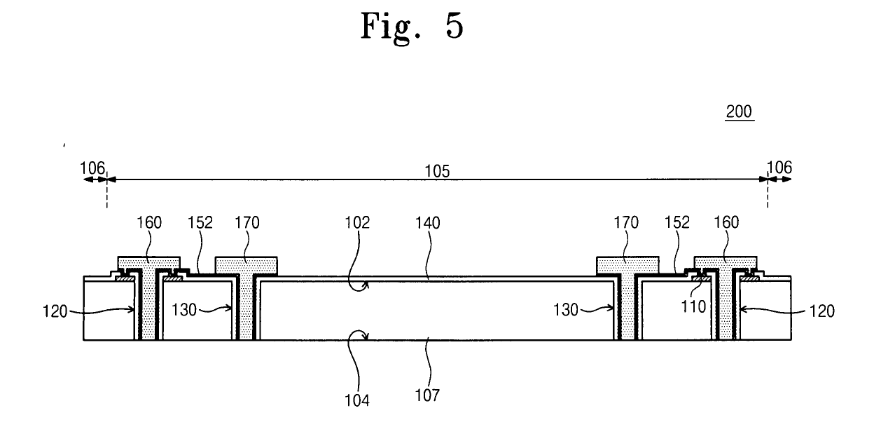

FIG. 5 is a cross-sectional view of a semiconductor device according to another embodiment of the present inventive concepts. The semiconductor device shown in FIG. 5 is identical or similar to that shown in FIG. 1. Therefore, only differences therebetween will be described below in detail but duplications will not be described or briefly described.

Similar to the semiconductor chip 100 shown in FIG. 1, a semiconductor chip 200 shown in FIG. 5 may include a semiconductor substrate 107 that may be divided into a cell area 105 and a scribe lane area 106. The cell area 105 may include a pad 110 disposed at a front face 102 of the substrate 107, a via hole 120 formed to vertically penetrate the pad 110 and the substrate 107, and a through electrode 160 buried in the via hole 120 to be electrically connected to the pad 110. The semiconductor chip 200 may include a passivation layer 140 covering the front face 102 of the substrate 107 to protect the front face 102 and covering an inner wall of the via hole 120 to electrically insulate the substrate 107 from the through electrode 160.

Unlike the semiconductor chip 100 shown in FIG. 1, the semiconductor chip 200 may include a dummy via hole 130 formed to penetrate the substrate 107 and a dummy through electrode 170 disposed to fill the dummy via hole 130. The dummy through electrode 170 may be provided at an unused position in the cell area 105. The dummy through electrode 170 may be electrically connected to the pad 110 by the medium of a conductive pattern 152. Thus, the through electrode 160 and the dummy through electrode 170 may be electrically connected in parallel to the pad 110.

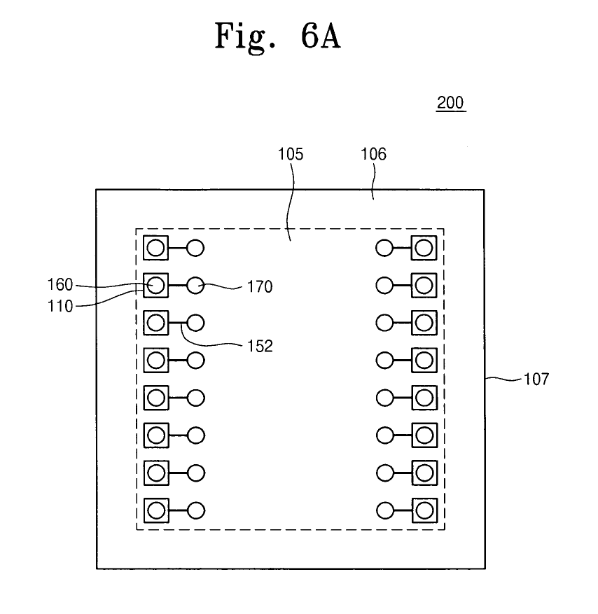

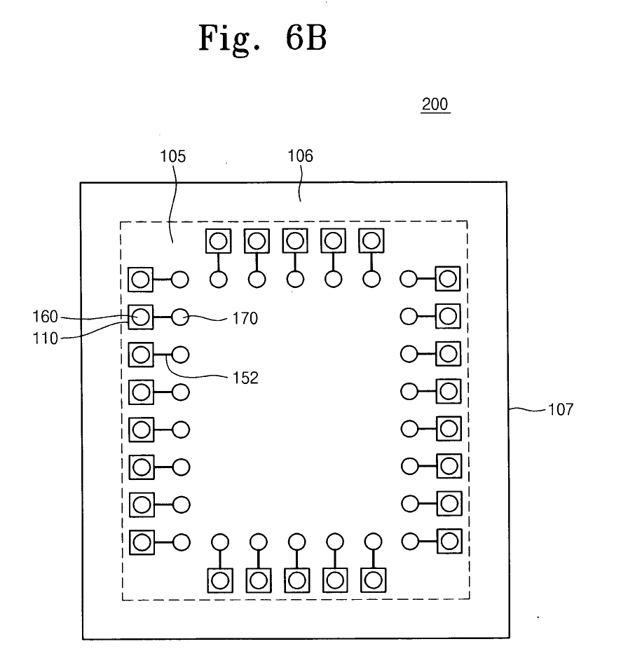

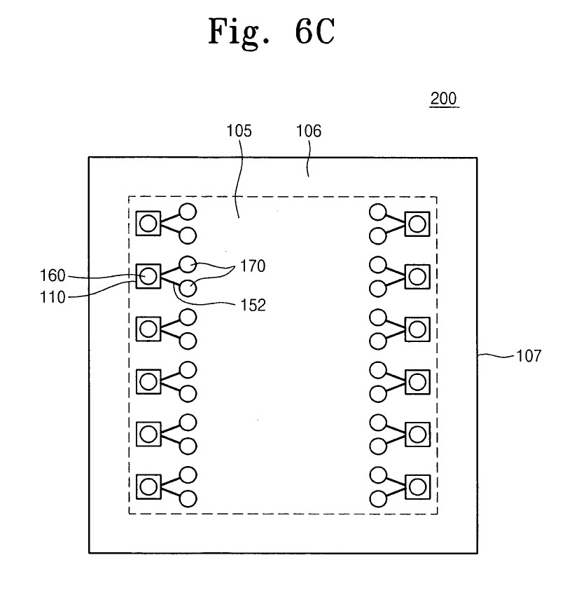

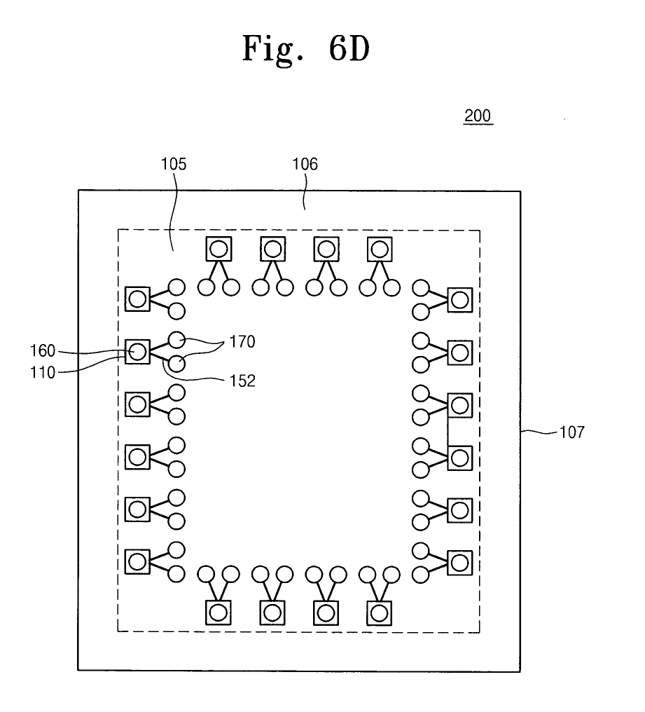

FIGS. 6A to 6D are top plan views of the semiconductor device shown in FIG. 5 according to various example embodiments of the inventive concepts.

FIG. 6A represents a top plan view of the semiconductor device 200 shown in FIG. 5 according to an example embodiment of the inventive concepts. Referring to FIG. 6A, a plurality of pads 110 may be arranged adjacent to both sides (left and right sides) of a cell area 105. Similar to the pads 110, a plurality of through electrodes 160 may be arranged adjacent to the left and right sides of the cell area 105. A plurality of dummy through electrodes 170 may be arranged inside the cell area 105 to establish a one-to-one correspondence to the through electrodes 160 and may be electrically connected to the through electrodes 160 by the medium of conductive patterns 152.

FIG. 6B represents a top plan view of the semiconductor device 200 shown in FIG. 5 according to another example embodiment of the inventive concepts. Referring to FIG. 6B, a plurality of pads 110 and a plurality of through electrodes 160 are arranged adjacent to four sides (upper, lower, left, and right sides) of the cell area 105. Similarly, a plurality of dummy through electrodes 170 electrically connected to the through electrodes 160 by the medium of the conductive patterns 152 may be arranged inside the cell area 106 to establish a one-to-one correspondence to the through electrodes 160.

FIG. 6C represents a top plan view of the semiconductor device 200 shown in FIG. 5 according to another example embodiment of the inventive concepts. Referring to FIG. 6C, one through electrode 160 may be connected to a plurality of dummy through electrodes 170. For example, two dummy through electrodes 170 may correspond to one through electrode 160. The other explanations may be identical to those of FIG. 6A.

FIG. 6D represents a top plan view of the semiconductor device 200 shown in FIG. 5 according to another example embodiment of the inventive concepts. Referring to FIG. 6D, at least two dummy through electrodes 170 may be electrically connected to one through electrode 160.

The parallel electrical structure and the electrical and mechanical characteristics (described in FIG. 3) as well as the semiconductor package where the same or different kinds of semiconductor chips are stacked (described in FIGS. 4A to 4C) may be applied to the semiconductor chip 200 described in FIG. 5 and FIGS. 6A to 6D.

FIGS. 7A to 7G are cross-sectional views illustrating a method for fabricating the semiconductor device according to an example embodiment of the present inventive concepts.

Referring to FIG. 7A, a substrate 101 may be provided. The substrate 101 may have a front face 102 and a back face 103 opposite to the front face 102 and include an integrated circuit (IC) such as a memory circuit or a logic circuit. The substrate 101 may be a semiconductor substrate such as a silicon wafer or a SOI substrate. According to the present example embodiment of the inventive concepts, the semiconductor substrate 101 may be a silicon wafer. The front face 102 may be an active face where an IC is formed, and the back face 104 may be an inactive face. The substrate 101 may be divided into a cell area 105 where an IC is formed and a scribe lane area 106 surrounding the cell area 105. An input/output pad 110 electrically connected to an IC may be formed on the front face 102 of the cell area 105. The pad 110 may be made of metal, such as aluminum or copper, or an alloy. In this specification, only a portion of the substrate 101 around the scribe lane area 106 is illustrated for the convenience of description.

Referring to FIG. 7B, a via hole 120 may be formed at the substrate 101 of the cell area 105. The via hole 120 may vertically extend from the front face 102 while not reaching the back face 103, i.e., exhibit the shape of a cylinder having a length that is smaller than a thickness of the substrate 101. The via hole 120 may be formed through the pad 110. The via hole 120 may be formed by means of a dry etch process, a wet etch process, a laser drilling process or a mechanical drilling process. The via hole 120 may also be formed using laser drilling by which depth or width (diameter) of the via hole 120 is relatively easily set by properly regulating a pulse or intensity of laser without fabricating a mask or performing a photolithography process.

A dummy via hole 130 may be formed in the scribe lane area 106 of the substrate 101. The method may adopt the case where the scribe lane area 106 is large enough to form a dummy via hole 130. In this example embodiment, it is appropriate that the method adopts a via last process.

The dummy via hole 130 may be formed using laser drilling simultaneously with, before or after formation of the via hole 120. According to this example embodiment, the via hole 120 and the dummy via hole 130 may be formed simultaneously and, thus, it is not necessary to perform an additional process. The shape and size of the dummy via hole 130 may be identical to or different from those of the via hole 120. The number of the via holes 130 is equal to or greater than that of the via holes 120. In this example embodiment, one dummy via hole 130 may be formed per one via hole 120 or two dummy via holes 130 may be formed per one via hole 120.

Referring to FIG. 7C, a passivation layer 140 may be formed on the substrate 101 to expose a portion of the pad 110. In this example embodiment, an insulating material (e.g., oxide such as silicon oxide, nitride such as silicon nitride or polymer such as parylene) may be deposited on the front face 102 of the substrate 101. The deposited insulating material may be patterned to form a passivation layer 140 having an opening 142 which exposes a portion of the pad 110. The opening 142 may be provided on the pad 110 to be in the form of a ring surrounding the circumference of the via hole 120.

In another example embodiment, a passivation layer 140 may be formed before formation of via holes 120 and 130, and a via hole insulating layer (not shown) may be formed to cover inner walls of the via holes 120 and 130 after formation of the via holes 120 and 130. However, if a passivation layer 140 is formed after formation of the via holes 120 and 130 (like the example embodiment illustrated in FIG. 7C), the passivation layer 140 may cover not only the front face 102 of the substrate 101 but also the inner walls of the via holes 120 and 130. Thus, because the example embodiment illustrated in FIG. 7C does not require a hole to be formed in an insulating layer, a process having a continuity of the layers may be obtained.

Referring to FIG. 7D, a conductive layer 150 may be formed on the substrate 101. In this example embodiment, the conductive layer 150 may be formed by depositing or plating a conductive material such as metal (e.g., copper, aluminum, titanium, nickel or alloy thereof) on the passivation layer 140 throughout the cell area 105 and the scribe lane area 106. The conductive layer 150 may also be formed at the opening 142 to contact the pad 110.

Referring to FIG. 7E, the conductive layer 150 may be patterned to form a conductive pattern 152. In this example embodiment, the conductive layer 150 may be formed by forming a photoresist pattern to form a portion of the conductive layer 150 and performing an etch process using the photoresist pattern as a mask to remove a portion of the conductive layer 150. The conductive pattern 152 may be in contact with the pad 110 via the opening 142, be disposed on the inner walls of the via holes 120 and 130 with the passivation layer 140 interposed therebetween, and be continuous between the via holes 120 and 130.

As will be described below with reference to FIG. 7F, the conductive pattern 152 may be used as a seed when a through electrode (160 of FIG. 7F) is formed by means of a plating process. As previously discussed with reference to FIG. 3, the conductive pattern 152 may be used as a redistribution layer which electrically connects the through electrode 160 and the dummy through electrode 170 to each other.

Referring to FIG. 7F, the via hole 120 may be filled with a conductor to form a through electrode 160. The dummy via hole 130 may also be filled with the conductor to form a dummy through hole 170. According to the example embodiments of the present inventive concepts, the through electrode 160 and the dummy through electrode 170 may be formed simultaneously and it is not necessary to perform an additional process.

In this example embodiment, the through electrodes 160 and 170 may be formed simultaneously by means of an electroplating process using the conductive pattern 152 as a seed. Thus, the through electrode 160 may be formed at the cell area 105 to fill the via hole 120 and contact the pad 110, and the dummy through electrode 170 may be formed at the scribe lane area 106 to fill the dummy via hole 130 and be electrically connected to the pad 110 by the conductive pattern 152. According to this example embodiment of the present inventive concepts, the conductive pattern 152 may be used as a redistribution pattern which electrically connects the through electrodes 160 and 170 to each other. In another example embodiment, a conductive material may be deposited and patterned on the front face 102 and the substrate 101 to form through electrodes 160 and 170.

Referring to FIG. 7G, the back surface 103 of the substrate 101 may be polished. This polishing may be performed down to a second back face 104 to expose lower ends of the through electrodes 160 and 170. As a result, a wafer-level semiconductor device 10 may be fabricated in which the through electrode 160 and the dummy through electrode 170 penetrating the substrate 107 having a polished back face 104 are formed at the cell area 105 and the scribe lane area 106, respectively. If the wafer-level semiconductor device 10 is cut along a scribe lane 108, a plurality of chip-unit semiconductor devices, i.e., semiconductor chips 100 may be obtained.

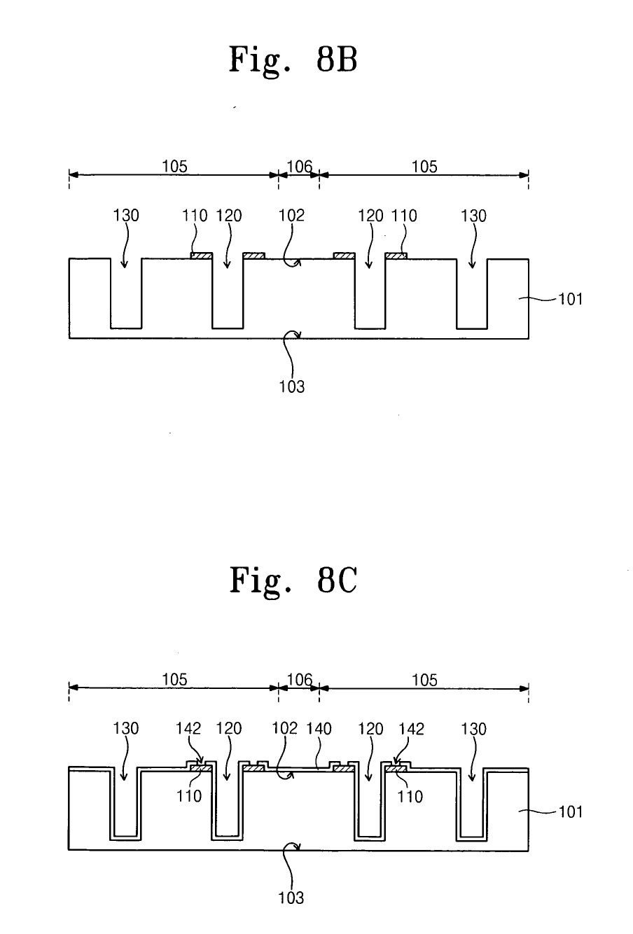

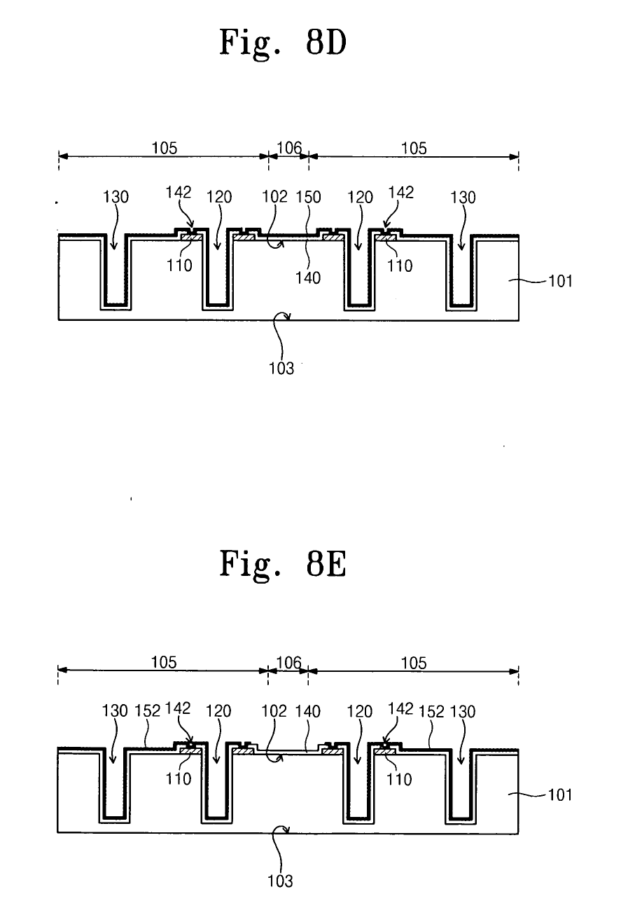

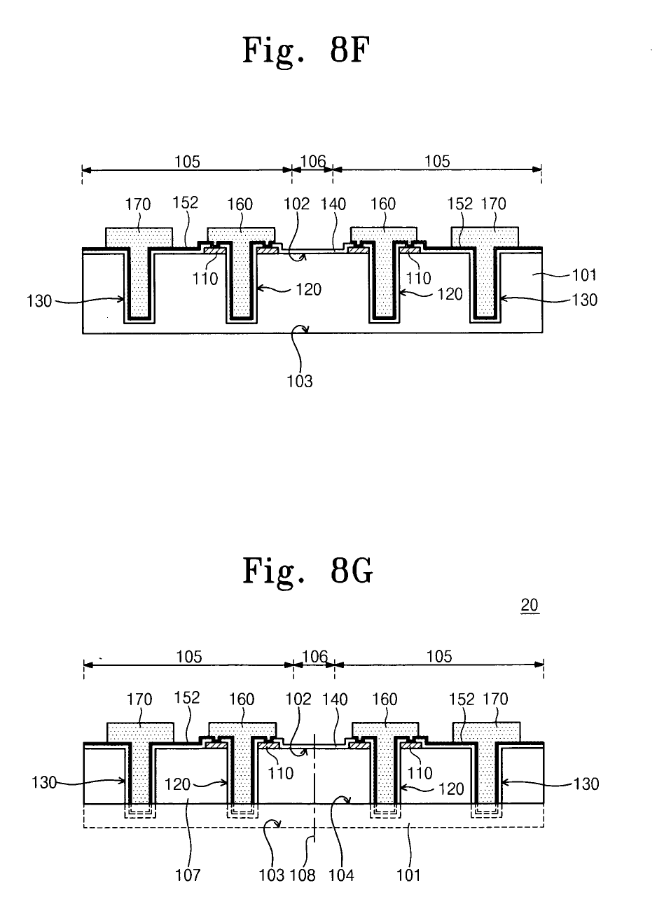

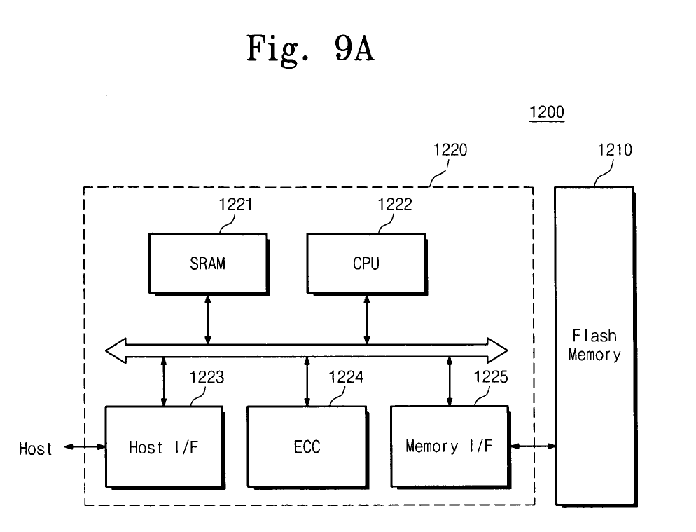

FIGS. 8A to 8G are cross-sectional views illustrating another method for fabricating the semiconductor device according to an example embodiment of the present inventive concepts.

The method illustrated with reference to FIGS. 8A to 8G are identical or similar to that illustrated with reference to FIG. 7A to 7G. Therefore, only the different parts will be explained in detail while the same parts will not be explained or will be omitted for the sake of brevity.

Referring to FIG. 8A, there may be provided a wafer-level semiconductor substrate 101 which may be divided into a cell area 105 and a scribe lane area 106. The substrate 101 may have a front face 102 being an active face and a back face 103 being an inactive face. A pad 110 may be formed on the front face 102 within the cell area 105.

Referring to FIG. 8B, a via hole 120 may be formed at the substrate 101 in the cell area 105. The via hole 120 may be formed by means of, for example, a laser drilling process to remove a portion of the pad 110 and the underlying substrate 101. A dummy via hole 130 may be formed in the cell area 105 of the substrate 101 at the same time of the via hole 120 is formed. The via hole 120 may be closer to the scribe lane area 106 than the dummy via hole 130. The number of the dummy via holes 130 may be equal to or greater than that of the via hole 120s. In an example embodiment, one or at least two via holes 130 may be formed per one via hole 120.

The foregoing method described with reference to FIGS. 7A to 7G adopts a via last process to form a dummy via hole 130 at a scribe lane area 106 in the case where the scribe lane area 106 has a sufficiently large size. However, if a size of the scribe lane area 106 is reduced to increase the number of semiconductor chips per wafer, it is difficult to form the dummy via hole 130 at the scribe lane area 106. Therefore, according to the method described with reference to FIGS. 8A to 8G, a dummy via hole 130 may be formed by selecting an unused area from the cell area 105. In this method, it is appropriate to adopt a via first process.

Referring to FIG. 8C, an insulating material may be deposited and patterned on the substrate 101 to form a passivation layer 140 having an opening 142 which may expose a portion of the pad 110. The passivation layer 140 may be formed to cover the front face 102 of the substrate 101 and the via holes 120 and 130. Thus, the passivation layer 140 may protect the front face 102 of the substrate 101 and cover the inner walls of the via holes 120 and 130 to electrically insulate the via holes 120 and 130 from the substrate 101.

Referring to FIG. 8D, a conductive layer 150 may be formed on the substrate 101. The conductive layer 150 may be formed on the passivation layer 140 by depositing or plating a conductive material such as a metal.

Referring to FIG. 8E, the conductive layer 150 may be patterned to form a conductive pattern 152. The conductive pattern 152 may be in contact with the pad 110 through the opening 142, be disposed on the inner walls of the via holes 120 and 130 with the passivation layer 140 interposed therebetween, and be continuous between the via holes 120 and 130. As will be described below with reference to FIG. 8F, the conductive pattern 152 may be used as a seed for a plating process. The conductive pattern 152 may be used as a redistribution layer to electrically connect a through electrode 160 and a dummy through electrode 170 to each other.

Referring to FIG. 8F, the via hole 120 may be filled with a conductor to form a through electrode 160. The dummy hole 130 may also be filled with a conductor to form a dummy through electrode 170 at the same time the through electrode 160 is formed. The through electrodes 160 and 170 may be simultaneously formed by means of an electroplating process using the conductive pattern 152 as a seed. Thus, the through electrode 160 being in contact with the pad 110 and the dummy through electrode 170 being electrically connected to the pad 110 by the conductive pattern 152 may be formed at the cell area 105.

Referring to FIG. 8G, the back face 103 of the substrate 101 may be polished to expose lower ends of the through electrodes 160 and 170 via the second back face 104. As a result, a wafer-level semiconductor device 20 may be fabricated in which the through electrode 160 and the dummy through electrode 170 are formed at the cell area 105 to penetrate the substrate having the polished back face 104. If the wafer-level semiconductor device 20 is divided along a scribe lane 108, a plurality of semiconductor chips 200 may be provided, as set forth in FIG. 5.

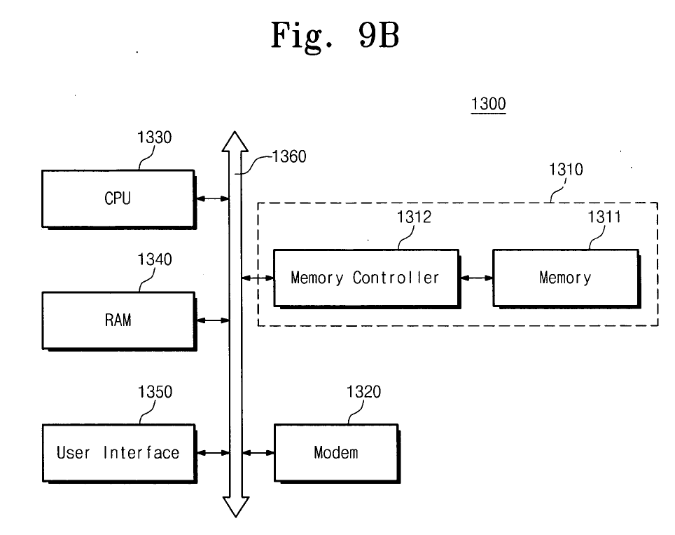

FIG. 9A is a block diagram of a memory card including a semiconductor device according to various example embodiments of the present inventive concepts.

Referring to FIG. 9A, the semiconductor device, e.g., a semiconductor memory 1210 may be applied to a memory card 1200. In an example embodiment, the memory card 1200 may include a memory controller 1220 that controls overall data exchange between a host and a memory 1210. An SRAM 1221 may be used as an operation memory of a central processing unit (CPU) 1222. A host interface 1223 may include a data exchange protocol of a host connected to the memory card 1200. An error correction code (EEC) 1224 may detect and correct an error included in data read out of the memory 1210. The memory interface 1225 interfaces with the memory 1210. The CPU 1222 performs an overall control operation for data exchange of the memory controller 1220.

FIG. 9B is a block diagram of a data processing system including a semiconductor device according to an example embodiment of the present inventive concepts.

Referring to FIG. 9B, an information processing system 1300 may include a memory system 1310 provided with a semiconductor device according to the present invention. The information processing system 1300 may include a mobile device, a computer or the like. In this example embodiment, the information processing system 1300 includes a flash memory system 1310, and a modem 1320, a central processing unit (CPU) 1330, a RAM 1340, and a user interface 1350 which are electrically connected to a system bus 1360. The memory system 1310 may be configured with the same structure as the memory card 1200 described with reference to FIG. 9A.

Data processed by the CPU 1330 or external input data may be stored in the flash memory system 1310. The information processing system 1300 may be provided in the form of a memory card, a solid state disk, a camera image sensor and other application chipset. In one example, the flash memory system 1310 may be configured with a semiconductor disk device (SSD). In this case, the information processing system 1300 can stably and reliably store high-capacity data in the flash memory system 1310.

Furthermore, the semiconductor device according to some example embodiments of the present inventive concepts may be mounted in various types of packages. Examples of the packages of the flash memory or flash memory systems according to some example embodiments of the inventive concepts may include package on package (PoP), ball grid arrays (BGAs), chip scale packages (CSPs), a plastic leaded chip carrier (PLCC), a plastic dual in-line package (PDIP), a multi chip package (MCP), a wafer-level package (WP), a wafer-level fabricated package (WFP), a wafer-level processed stack package (WSP), a die in waffle pack, a die in wafer form, a chip on board (COB), a ceramic dual in-line package (CERDIP), a plastic metric quad flat pack (MQFP), a thin quad flat pack (TQFP), a small outline package (SOP), a shrink small outline package (SSOP), a thin small outline package (TSOP), a thin quad flat package (TQFP), a system in package (SIP) and so on.

Disclosed herein are example embodiments of the present inventive concepts. The example embodiments include parallel electrical connections which are achieved by forming a dummy through electrode connected to a through electrode via a redistribution line at a cell area or a scribe lane. Thus, electrical signal transmission and mechanical adhesion strength are promoted to improve electrical and mechanical characteristics of a semiconductor device.

While the present invention has been illustrated by description of example embodiments thereof and while the example embodiments have been described in considerable detail, it is not intended to restrict or in any way limit the scope of the appended claims to such details. Additional advantages and modifications in the spirit and scope of the present invention will readily appear to one skilled in the art. Therefore, the present invention is not limited to the specific details and illustrative examples shown and described.

1. A semiconductor device comprising:
a substrate including a cell area and a scribe lane area defining the cell area;
at least one pad on the cell area;
at least one through electrode penetrating the substrate and electrically connected to the at least one pad;
at least one dummy through electrode penetrating the substrate and spaced apart from the at least one through electrode; and
at least one conductive pattern on the substrate electrically connecting the at least one through electrode to the at least one dummy through electrode.

2. The semiconductor device as set forth in claim 1, wherein
the at least one through electrode is in the cell area, and
the at least one dummy through electrode is in one of the cell area and the scribe lane area.

3. The semiconductor device as set forth in claim 1, wherein
there is one of a one-to-one and one-to-many correspondence between the at least one through electrode and the at least one dummy through electrode.

4. The semiconductor device as set forth in claim 1, wherein
the at least one conductive pattern contacts the at least one pad and extends toward the at least one dummy through electrode from the at least one through electrode.

5. The semiconductor device as set forth in claim 1, wherein
the at least one through electrode penetrates the at least one pad.

6. The semiconductor device as set forth in claim 1, wherein
the at least one through electrode is a plurality of through electrodes arranged in two parallel lines in the cell area,
the at least one dummy through electrode is a plurality of dummy through electrodes arranged in two parallel lines in one of the scribe lane area and the cell area, and
the at least one conductive pattern is a plurality of conductive patterns connecting the plurality of through electrodes to the plurality of dummy through electrodes.

7. The semiconductor device as set forth in claim 1, wherein
the at least one through electrode is a plurality of through electrodes arranged in a rectangular pattern in the cell area,
the at least one dummy through electrode is a plurality of dummy through electrodes arranged in a rectangular pattern in one of the scribe lane area and the cell area, and
the at least one conductive pattern is a plurality of conductive patterns connecting the plurality of through electrodes to the plurality of dummy through electrodes.

8. The semiconductor device as set forth in claim 1, wherein
the at least one through electrode is a plurality of through electrodes in the cell area,
the at least one dummy through electrode is a plurality of dummy through electrodes in one of the scribe lane area and the cell area, and
the at least one conductive pattern is a plurality of conductive patterns connecting the plurality of through electrodes to the plurality of dummy through electrodes so that each of the through electrodes of the plurality of through electrodes is electrically connected to at least two dummy through electrodes of the plurality of dummy through electrodes.

9. The semiconductor device as set forth in claim 1, wherein
the at least one through electrode covers an opening in the at least one conductive pattern.

10. A semiconductor device comprising:
a plurality of stacked semiconductor chips, each of the semiconductor chips of the plurality of stacked semiconductor chips including,
a substrate where a pad is provided,
a through electrode electrically penetrating the substrate and electrically connected to the pad, and
a dummy through electrode penetrating the substrate and electrically connected to the through electrode via a conductive pattern,
wherein each of the through electrodes and each of the dummy through electrodes vertically contact each other and electrically connect to each other to make a parallel electrical connection.

11-20. (canceled)
